(19) United States
(12) Patent Application Publication
(10) Pub. No.: US 2024/0136180 A1
(43) Pub. Date: Apr. 25, 2024

(54) Diamond-Capped Gallium Oxide Transistor

(71) Applicant: The Government of the United States of America, as represented by the Secretary of the Navy, Arlington, VA (US)

(72) Inventors: Marko J. Tadjer, Vienna, VA (US); Joseph A. Spencer, Springfield, VA (US); Alan G. Jacobs, Rockville, MD (US); Hannah N. Masten, Alexandria, VA (US); James Spencer Lundh, Gaithersburg, MD (US); Karl D. Hobart, Alexandria, VA (US); Travis J. Anderson, Alexandria, VA (US); Tatyana I. Feygelson, Springfield, VA (US); Bradford B. Pate, Arlington, VA (US); Boris N. Feigelson, Springfield, VA (US)

(73) Assignee: The Government of the United States of America, as represented by the Secretary of the Navy, Arlington, VA (US)

(21) Appl. No.: 18/490,878

(22) Filed: Oct. 19, 2023

Related U.S. Application Data
(60) Provisional application No. 63/418,180, filed on Oct. 21, 2022.

(51) Int. Cl. H01L 21/02; H01L 29/24; H01L 29/778; H01L 29/78; H01L 29/80

(52) U.S. Cl. CPC H01L 21/02565; H01L 21/02304; H01L 21/02527; H01L 21/0262; H01L 29/24; H01L 29/7787; H01L 29/785; H01L 29/802

(57) ABSTRACT

A method for growing nanocrystalline diamond (NCD) on Ga₂O₃ to provide thermal management in Ga₂O₃-based devices. A protective SiNₓ interlayer is deposited on the Ga₂O₃ before growth of the NCD layer to protect the Ga₂O₃ from damage caused during growth of the NCD layer. The presence of the NCD provides thermal management and enables improved performance of the Ga₂O₃-based device.

### CROSS-REFERENCE

This Application is a Nonprovisonal of and claims the benefit of priority under 35 U.S.C. § 119 based on U.S. Provisional Patent Application No. 63/418,180 filed on Oct. 21, 2022. The Provisional Application and all references cited herein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; techtran@nrl.navy.mil, referencing Navy Case #211207.

### TECHNICAL FIELD

The present invention relates to the field of semiconductors and semiconductor devices, particularly to the field of thermal management in semiconductor devices.

### BACKGROUND

Gallium oxide is an attractive material for power electronics due to its ultra-wide bandgap (4.6-4.9 eV), which gives rise to a very high critical electric field (6-8 MV/cm) and a substantially higher Baliga Figure of Merit (BFOM) for this material compared to wide bandgap technologies based on gallium nitride and silicon carbide semiconductors. See M. Higashiwaki, “β-Gallium Oxide Devices, Progress and Outlook,” Phys. Status Solidi RRL, 15, 2100357 (2021) (“Higashiwaki 2021”). Significant efforts to develop this material into a technological platform for high-power, fast-switching electronic devices in recent years has brought together researchers in the fields of crystal growth, epitaxial film development, materials scientists, and electronic device. See M. Higashiwaki et al., “Gallium oxide (Ga₂O₃) metal-semiconductor field-effect transistors on single-crystal β-Ga₂O₃ (010) substrates,” Appl. Phys. Lett. 100, 013504 (2012) (“Higashiwaki 2012”); S. J. Pearton, et al., “A review of Ga₂O₃ materials, processing, and devices,” Applied Physics Reviews 5, 011301 (2018); Andrew J. Green, et al., “β-Gallium oxide power electronics,” APL Materials 10, 029201 (2022); and Joseph A. Spencer, et al., “A review of band structure and material properties of transparent conducting and semiconducting oxides: Ga₂O₃, Al₂O₃, In₂O₃, ZnO, SnO₂, CdO, NiO, CuO, and Sc₂O₃,” Applied Physics Reviews 9, 011315 (2022).

Recent developments have resulted in large-area substrates and epitaxial wafers, demonstration of shallow donors in Ga₂O₃ and its ternary alloy, β-(AlₓGa₁₋ₓ)₂O₃, lateral transistors with high breakdown voltage, and vertical transistor architectures such as the Fin-FET and current aperture FET (CAVET) that show exceptional promise for next-generation power electronics. See Akito Kuramata et al., “High-quality β-Ga2O3 single crystals grown by edge-defined film-fed growth,” Japanese Journal of Applied Physics 55, No. 12 (2016): 1202A2; Adam T. Neal, et al., “Donors and deep acceptors in β-Ga2O3,” Applied Physics Letters 113, No. 6 (2018); Darshana Wickramaratne, et al., “Donor doping of corundum (AlₓGa₁₋ₓ)₂O₃,” Applied Physics Letters 121, No. 4 (2022); Arkka Bhattacharyya, et al. “4.4 kV β-Ga₂O₃ MESFETs with power figure of merit exceeding 100 MW cm⁻²,” Applied Physics Express 15, No. 6 (2022): 061001; and Man Hoi. Wong et al., “Vertical β-Ga₂O₃ power transistors: A review.” IEEE Transactions on Electron Devices 67, No. 10 (2020): 3925-3937.

However, two challenges in development of Ga₂O₃-based devices persist: the ultra-low thermal conductivity of Ga₂O₃ and the impossibility of generating free hole carriers in this material due to self-trapping phenomena.

The low thermal conductivity of β-Ga₂O₃ is a well-known challenge for devices based on this ultra-wide bandgap semiconductor. See C. Yuan, et al., “Modeling and analysis for thermal management in gallium oxide field-effect transistors,” J. Appl. Phys. 127, 154502 (2020). The extremely low thermal conductivity of β-Ga₂O₃ lead to severe self-heating, placing a significant thermal limit on output power densities of devices based on β-Ga₂O₃ thereon, resulting in severely limited device reliability. The development of high-performance β-Ga₂O₃-based power devices will thus require the incorporation of thermal management solutions, e.g. wafer bonding to a high thermal conductivity substrate, a top-side heat spreaders, advanced packaging, microfluidic cooling, or a combination thereof. See Higashiwaki 2021, supra.

One solution that has been used in other wide bandgap electronic devices such as GaN high electron mobility transistors is the incorporation of nanocrystalline diamond (NCD) into the device fabrication process, either as a diamond capping layer, a polycrystalline diamond substrate, or a feature within the existing substrate, see, e.g., U.S. Pat. No. 9,159,641 to Hobart et al., “Nanocrystalline Diamond Three-Dimensional Films in Patterned Semiconductor Substrates”; U.S. Pat. No. 9,305,858 to Hobart et al., “Nanocrystalline Diamond Three-Dimensional Films in Patterned Semiconductor Substrates”; U.S. Pat. No. 11,131,039 to Hobart et al., “Diamond on Nanopatterned Substrate”; and U.S. Pat. No. 11,634,834 to Hobart et al., “Diamond on Nanopatterned Substrate”; as an infill to thermal vias, see, e.g., U.S. Pat. No. 9,196,703 to Hobart et al., “Selective Deposition of Diamond in Thermal Vias”; or as a component of the electronic device, see, e.g., U.S. Pat. No. 9,331,163 to Koehler et al., “Transistor with Diamond Gate”; U.S. Pat. No. 9,466,684 to Koehler et al, “Transistor with Diamond Gate”; U.S. Pat. No. 10,312,175 to Hobart et al., “Diamond Air Bridge for Thermal Management of High Power Devices”; and U.S. Pat. No. 10,424,623 to Hobart et al., “Diamond Air Bridge for Thermal Management of High Power Devices.”

All of these devices, however are based on GaN rather than Ga₂O₃. Although there have been attempts to grow diamond thin films onto Ga₂O₃-based substrates, See M. Malakoutian et al., “Polycrystalline diamond growth on β-Ga₂O₃ for thermal management,” 2021 Appl. Phys. Express 14 055502, attempts to incorporate NCD films into Ga₂O₃-based electronic devices to alleviate self-heating and improve output power density has faced several challenges.

First, hydrogen plasma present during chemical vapor deposition (CVD) of diamond will etch an unprotected Ga₂O₃ surface aggressively, necessitating a protective layer to be deposited onto Ga₂O₃ prior to diamond CVD. This layer has to be optimized such that it is not too thick, or else the thermal benefit of nanodiamond would not be optimal, and not too thin or else the protection of the Ga₂O₃ will not be effective.

Pinholes in the layer, a common defect in thin films, are also not acceptable and will result in large pits etched into the Ga₂O₃ crystal.

A barrier layer has also been necessary for CVD diamond growth on GaN. A dielectric layer such as silicon nitride has been used with good results in the past, allowing CVD growth of NCD at conditions similar to those of growth on silicon, silicon carbide, or other materials which do not require surface protection during NCD deposition.

In the case of Ga₂O₃, in addition to a barrier SiNₓ layer, a reduction in NCD growth temperature has been necessary as well, resulting in reduced growth rate and reduced NCD thermal conductivity. Future optimization of NCD growth conditions, such as introduction of small amounts of oxygen into the CVD process or depositing more robust barrier dielectrics such as SiC or B₄C, may alleviate these issues

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a solution to the self-heating problems of Ga₂O₃-based electronic devices by providing a method for incorporating NCD into the devices to provide thermal management and by providing Ga₂O₃-based devices that incorporate one or more NCD layers. The present invention overcomes the problems of incorporating such NCD layers into Ga₂O₃-based devices by depositing a protective interlayer onto the Ga₂O₃ layer before growth of the NCD layer to protect the Ga₂O₃ from damage caused during growth of the NCD layer.

In many embodiments, the protective interlayer will be in the form of a dielectric layer such as a SiNₓ layer deposited on an upper surface of the Ga₂O₃ barrier layer in the device. The presence of the protective dielectric interlayer prevents etch damage to the Ga₂O₃ surface caused by hydrogen plasma during diamond CVD growth and enables the formation of a high-quality continuous NCD layer which can provide effective thermal management and thereby reduce self-heating in the device.

The thickness of the SiNₓ interlayer can be tuned to minimize thermal resistance from the Ga₂O₃ device layer into the NCD heat spreading layer. For example, the thickness of the SiNₓ layer can be decreased, e.g., to 5-10 nm, to improve the impact of the NCD on thermal management in the device or can be increased, e.g., to 50-100 nm, to provide additional protection of the Ga₂O₃ layer.

In other embodiments, growth conditions of the NCD layer such as growth temperatures, pressure, methane/hydrogen precursor flow rate, and power can be tuned, e.g., to provide a high quality, continuous layer of NCD at close proximity to the Ga₂O₃ layer.

### BRIEF DESCRIPTION OF THE DRAWINGS

FIG. 1 is a block schematic illustrating an exemplary Ga₂O₃-based electronic device incorporating an NCD heat-spreading layer in accordance with the present invention.

FIGS. 2A-2F are a β-series of atomic force microscope (AFM) images showing NCD films grown on Ga₂O₃ at 400° C. and 500° C. with three different SiNₓ barrier dielectric layers.

FIGS. 3A and 3B are SEM images illustrating how a barrier dielectric layer in accordance with the present invention protects an NCD-coated Ga₂O₃ crystal during an H₂ plasma etch.

FIG. 4 is a plot showing Raman spectra confirming growth of NCD on Ga₂O₃ having the various SiNₓ barrier dielectrics shown in FIGS. 2D-2F.

FIG. 5 is a plot showing Raman spectra confirming growth of NCD on Ga₂O₃ with a protective interlayer up to a temperature of 650° C.

FIGS. 6A and 6B are plots showing DC transfer curves for β-Ga₂O₃ devices without (FIG. 6A) and with (FIG. 6B) NCD/SiNₓ layers in accordance with the present invention.

FIGS. 7A and 7B are plots showing DC output curves for β-Ga₂O₃ devices without (FIG. 7A) and with (FIG. 7B) NCD/SiNₓ layers in accordance with the present invention.

FIG. 8 is a plot illustrating the average temperature rise as a function of power density for HFET devices with and without NCD/SiNₓ layers in accordance with the present invention.

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

For example, although the present invention will be described below in the context of an exemplary Ga₂O₃-based heterostructure grown via ozone-assisted molecular beam epitaxy (O₃-MBE), one skilled in the art will readily recognize that heterostructures having other configurations or grown by other means can also benefit from thermal management provided by incorporation of an NCD layer with protective interlayer disposed between the NCD and the Ga₂O₃, and all such alternative heterostructures are deemed to be within the scope of the present disclosure.

As described above, the low thermal conductivity of β-Ga₂O₃ is a significant concern for maximizing the potential of this ultra-wide bandgap semiconductor technology, but previous attempts to incorporate NCD into Ga₂O₃-based devices have not been successful.

The present invention overcomes the problems of incorporating NCD into such Ga₂O₃-based devices. In accordance with the present invention, a protective interlayer is deposited onto the Ga₂O₃ layer before growth of the NCD layer to protect the Ga₂O₃ from damage caused during growth of the NCD layer. In this way, the present invention enables the formation of devices that incorporate NCD as a top-side, device-level thermal management solution on a lateral β-Ga₂O₃ transistor.

In many embodiments, the protective interlayer will be in the form of a dielectric layer such as a SiNₓ layer deposited on an upper surface of the Ga₂O₃ barrier layer in the device. The presence of the protective dielectric interlayer prevents etch damage to the Ga₂O₃ surface caused by hydrogen plasma during diamond CVD growth and enables the formation of a high-quality continuous NCD layer which can provide effective thermal management and thereby reduce self-heating in the device.

Thus, as described in more detail below, in accordance with the present invention, an NCD heat-spreading layer is grown via microwave plasma enhanced chemical vapor deposition on a Ga₂O₃ layer in a Ga₂O₃-based heterostructure, where a protective dielectric interlayer such as a SiNₓ layer is deposited on the Ga₂O₃ layer prior to growth of the NCD layer to protect the surface of the Ga₂O₃ from damage caused by the diamond deposition conditions.

In many embodiments, the Ga₂O₃-based structure is a β-(AlₓGa₁₋ₓ)₂O₃/β-Ga₂O₃ heterostructure, with the NCD being deposited prior to the gate formation, though other embodiments in which the NCD layer is deposited after the Ni/Au gate contact or, conversely, the Ni/Au gate is deposited onto an existing NCD layer, are also possible.

The incorporation of the NCD heat-spreading layer enables the formation of a β-(AlₓGa₁₋ₓ)₂O₃/β-Ga₂O₃ heterostructure field-effect transistor (HFET) showing a decrease in total thermal resistance at the gate by >40%.

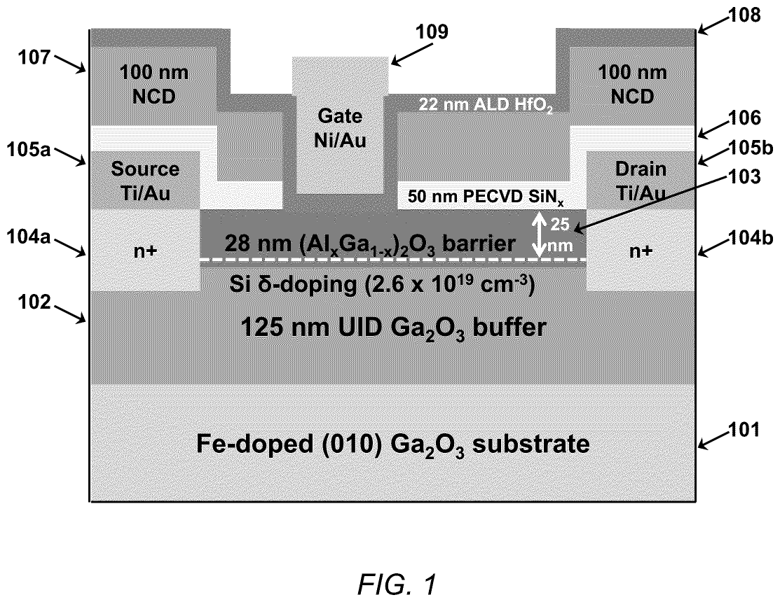

FIG. 1 illustrates an exemplary embodiment of a β-(AlₓGa₁₋ₓ)₂O₃/Ga₂O₃ heterostructure field-effect transistor (HFET) incorporating a nanocrystalline diamond (NCD) heat-spreading layer and SiNₓ protective interlayer in accordance with the present invention. As noted above, in the embodiment illustrated in FIG. 1, the NCD layer was etched prior to deposition of the Ni/Au gate contact, but other embodiments in which the NCD layer is deposited after the Ni/Au gate contact or, conversely, the Ni/Au gate is deposited onto an existing NCD layer, are also possible.

As illustrated in FIG. 1, such an exemplary device can comprise a 125 nm-thick unintentionally doped (UID) Ga₂O₃ buffer layer 102 grown on an Fe-doped (010) Ga₂O₃ substrate 101, with a 28 nm-thick (AlₓGa0₁₋ₓ)₂O₃ barrier layer 103 disposed on the Ga₂O₃ layer, where the AlGaO layer 103 is delta-doped with Si approximately 3 nm above its interface with Ga₂O₃ layer 102 (i.e., approximately 25 nm from the top of the layer in the case shown in the FIGURE). Si ions are implanted and annealed in an N₂ atmosphere for 30 min at 925° C. to form n+ areas 104a/104b for the source and drain, respectively, with Ti/Au being deposited by e-beam evaporation on each of the n+ areas and annealed in an N₂ atmosphere for approximately one minute at 470° C. to form Ohmic source/drain contacts 105a/105b. The specific contact resistivity, mobility, sheet carrier concentration, and sheet resistance of this structure at room temperature were measured as follows:

| | |
|---|---|
| contact resistivity | 4.3 × 10⁻⁴ Ω × cm² |
| mobility | 54 cm²/V · s |
| sheet carrier concentration | 1.26 × 10¹³ cm⁻² |
| sheet resistance | 9.1 kΩ/square |

In accordance with the present invention, a SiNₓ layer 106 having an exemplary thickness of about 50 nm was then deposited by plasma-enhanced chemical vapor deposition (PECVD) at 400° C. The presence of the SiNₓ layer protects the Ga₂O₃ layer from damage caused by the H₂ plasma required for growth of NCD layer 107.

NCD layer 107 was then grown on the Ga₂O₃ layer as protected by the SiNₓ layer. The NCD layer can be grown by any suitable process, but typically will be grown via microwave plasma enhanced chemical vapor deposition (MW-CVD). To start the NCD growth process, nucleation sites for the growth of NCD layer 107 were facilitated via a seeding method using detonation nanodiamond powder. In an exemplary case, the growth chamber was pre-treated with 200 sccm of H₂ at a temperature of 100° C. and a pressure of 15 torr for 1 hour. NCD growth was then performed using a 1.5% CH₄/H₂ concentration at a temperature of 400° C., pressure of 15 Torr, and power of 800 W for about 6 hours to produce an NCD film having a thickness of about 100 nm. Growth temperature for the NCD can range up to 650° C., with the other parameters also being adjustable as appropriate, i.e., power can range from 500-1000 W, pressure can range from 5-20 Torr, and the CH₄/H₂ concentration can range from 0.5 to 3%, with the specific values of each of these parameters depending on the process conditions and the intended end use of the device.

The NCD layer and SiNₓ interlayer were then etched to expose the source/drain metal contacts on which electrical connections are made and to define the gate region. In an exemplary embodiment, this etching can be performed using an O₂ inductively coupled plasma (ICP) etch of the NCD layer at 1000 W ICP power and 100 W reactive-ion etch (RIE) power, followed by an ICP-RIE SF₆ etch of the SiNₓ interlayer at ICP 200 W, RIE 50 W, but other suitable etching conditions can be used, e.g., pressures of about 5 mT, O₂ flow rate of 10-50 sccm, and temperatures of about 20-30° C. In other embodiments, the etch can be performed using a SF₆ plasma rather than an O₂ plasma.

Following the etching of the NCD and SiNₓ, a 22 nm HfO₂ gate dielectric layer 108 was then deposited by atomic layer deposition (ALD) on the upper surface of the NCD layer and the sides and bottom of the etched trench, and finally the gate contacts 109 were formed by depositing a 20/200 nm thick Ni/Au metal stack into the thus-defined trench.

Other etching regimes can also be used to define the gate area. For example, in some embodiments, a SiNₓ mask can be deposited on an upper surface of the NCD layer to protect the NCD surface during the SF₆ etch, while in other embodiments, a wet etching (e.g., using buffered HF) can be used on the SiNₓ interlayer to minimize plasma damage to the Ga₂O₃ active region. In still other embodiments, the gate area can be defined by etching the SiNₓ layer before the growth of the NCD layer.

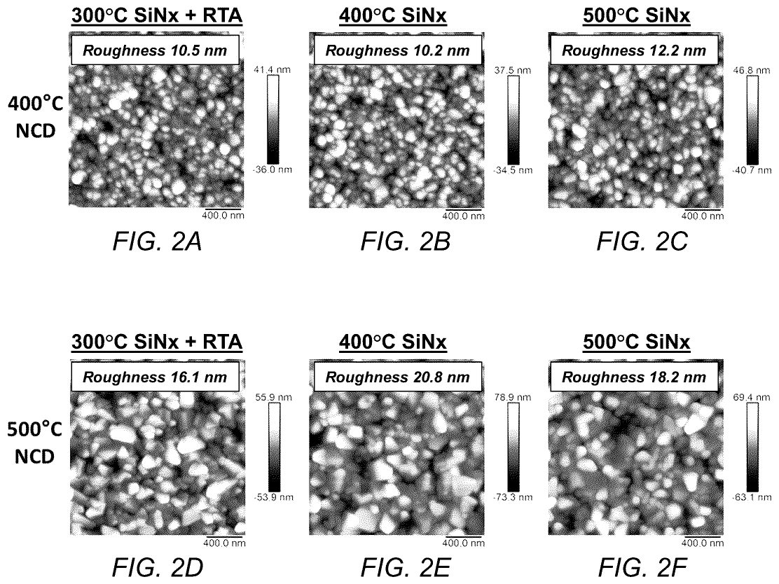

FIGS. 2A-2F are a β-series of atomic force microscope (AFM) images showing NCD films grown on Ga₂O₃ at 400° C. (FIGS. 2A-2C) and 500° C. (FIGS. 2D-2F) with different SiNₓ barrier dielectric layers, i.e., with a rapid-thermal annealed (RTA) SiNₓ barrier layer deposited at 300° C. (FIGS. 2A and 2D), a SiNₓ barrier layer deposited at 400° C. (FIGS. 2B and 2E), and a SiNₓ barrier layer deposited at 500° C. (FIGS. 2C and 2F). The different deposition and annealing conditions of the SiNₓ layers were aimed at densifying these dielectric layers in order to reduce their etch rate during NCD deposition as much as possible.

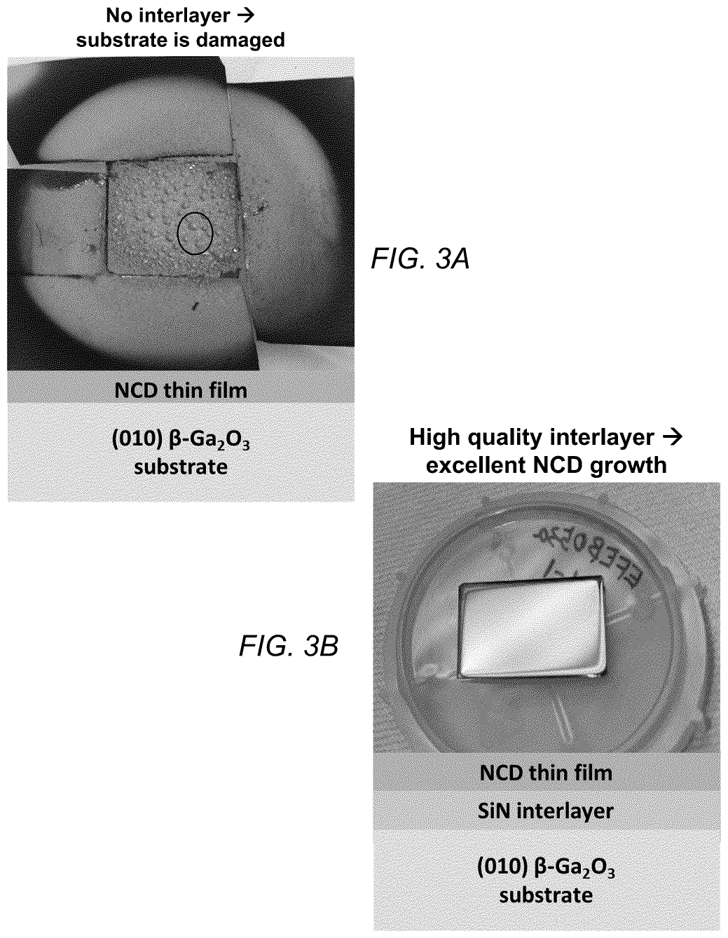

The SEM images in FIGS. 3A and 3B show how a barrier dielectric layer in accordance with the present invention protects an NCD-coated Ga₂O₃ crystal during an H₂ plasma etch. As can be seen from the image in FIG. 3A, an NCD-coated Ga₂O₃ crystal that is not protected with a dielectric coating is damaged during the etch, with multiple gallium droplets being readily visible on the surface of the crystal. In contrast, the NCD-coated Ga₂O₃ crystal shown in FIG. 3B includes a properly deposited barrier dielectric, and exhibits a smooth, continuous NCD layer on the surface of the Ga₂O₃.

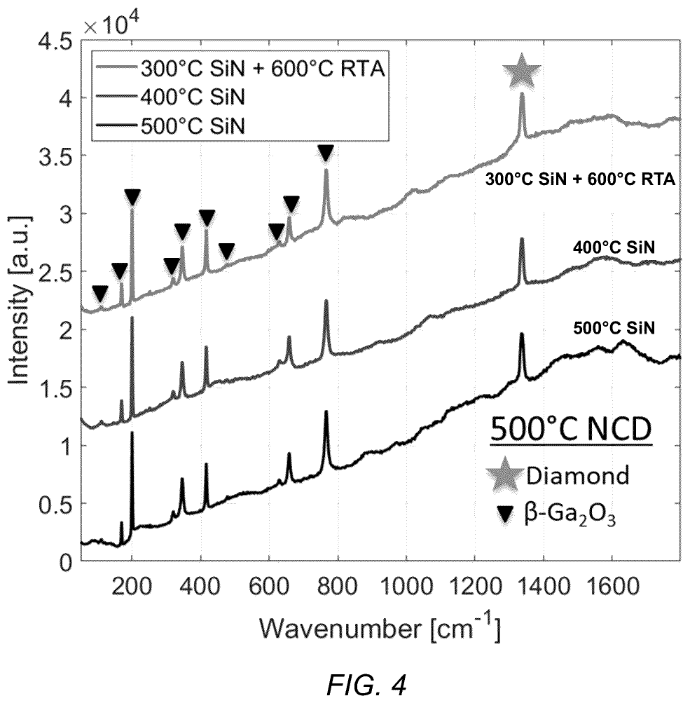

The plot in FIG. 4 shows Raman spectra measured on the NCD samples grown on Ga₂O₃ at 500° C. with different SiNₓ dielectric interlayers shown in FIGS. 2D-2F. These spectra show both the signature Raman mode of sp3-bonded diamond and the signature Raman modes of monoclinic β-Ga₂O₃, confirming growth of the high quality NCD film on β-Ga₂O₃ without compromising the Ga₂O₃ quality. This would not be possible to do on a wafer scale without the use of a barrier dielectric such as SiNₓ, precluding the use of NCD as top-side heat spreading layer for thermal management of Ga₂O₃ electronic devices.

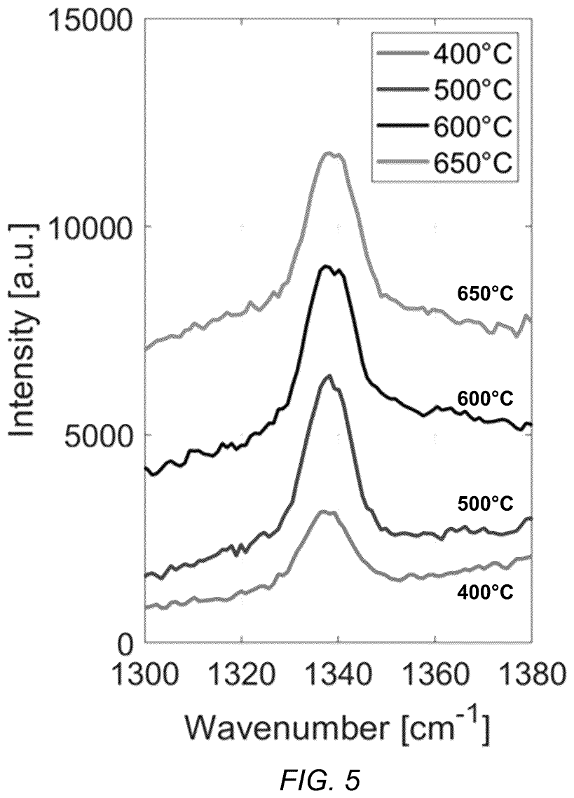

The plot in FIG. 5 shows Raman spectra of NCD films grown on Ga₂O₃ with a protective SiNₓ interlayer in accordance with the present invention up to a temperature of 650° C. The presence of a Raman peak near 1340 cm⁻¹, specifically at 1332.5 cm⁻¹, confirms the covalent sp3 bonding of the deposited NCD layer. The higher NCD deposition temperature leads to increased NCD grain size and thermal conductivity without compromising the underlying Ga₂O₃ layers, enabling more efficient heat spreading compared to NCD grown at a lower temperature, e.g., at 400° C.

Thus, as confirmed by the Raman spectra in FIGS. 4 and 5, high-quality NCD thermal management layers can successfully be grown on Ga₂O₃ having a SiNₓ interlayer deposited thereon before growth of the NCD, in accordance with the present invention.

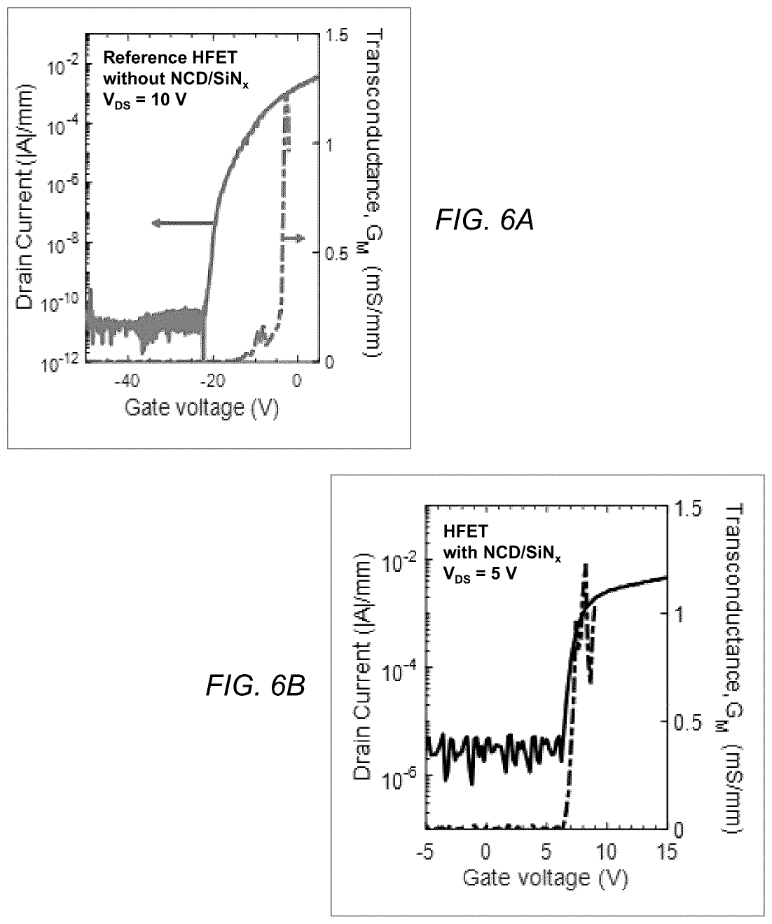

To test the performance of a device having a structure such as that illustrated in FIG. 1, on-state drain current was measured via DC current-voltage testing for a reference HFET lacking an NCD/SiNₓ stack in accordance with the present invention (FIG. 6A) and an HFET having an NCD/SiNₓ stack in accordance with the present invention (FIG. 6B).

As can be seen from the plots in FIGS. 6A and 6B, the reference device without the incorporation of an NCD/SiNₓ stack (FIG. 6A) is in a depletion mode or “normally-on,” and has a much larger on/off current ratio than is exhibited by a device having an NCD/SiNₓ stack in accordance with the present invention (FIG. 6B), i.e., V_{DS}=10V vs. V_{DS}=5V. By etching through the NCD/SiNₓ layers above the gate in a device in accordance with the present invention, as illustrated in FIG. 1, enhancement mode, or “normally-off” device behavior, can be achieved. It is well known that enhancement mode transistors are highly desirable for operational safety of power electronic systems, and so the present invention enables the formation of these highly desirable devices.

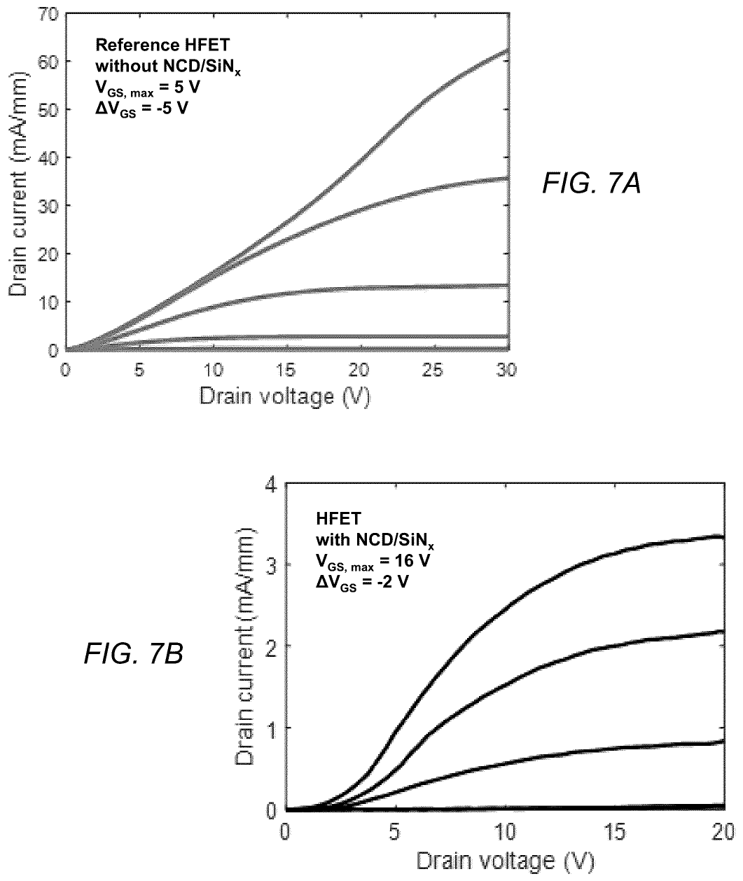

The plots in FIGS. 7A and 7B show the DC output curves for the devices with and without an NCD/SiNₓ stack discussed above with respect to FIGS. 6A and 6B. As can be seen by the plots in FIGS. 7A and 7B, the reference device without the NCD/SiNₓ stack in accordance with the present invention (FIG. 7A) shows a 20× higher drain current compared to the device having such a stack (FIG. 7B). That is, as illustrated by the plot in FIG. 7B, a lower drain current is seen in the device having the NCD/SiNₓ stack, likely due to the plasma damage to the β-(AlₓGa₁₋ₓ)₂O₃ active region during diamond formation in the structure without the protective dielectric layer. Although lower drain current is observed, we still achieve current modulation with this device structure. Improvement to the NCD/SiNₓ removal process during gate formation will result in higher drain current.

Thermal measurements of devices with and without an NCD/SiNₓ stack were performed using a TMX Scientific T° Imager (532 nm, 100× objective) at a base temperature maintained at 20° C. Power dissipated in the device was monitored using an oscilloscope. A maximum power density of ˜0.6.58 W/mm, with a gate voltage of 0 V, was measured before catastrophic failure occurred on the “Gate on NCD” device.

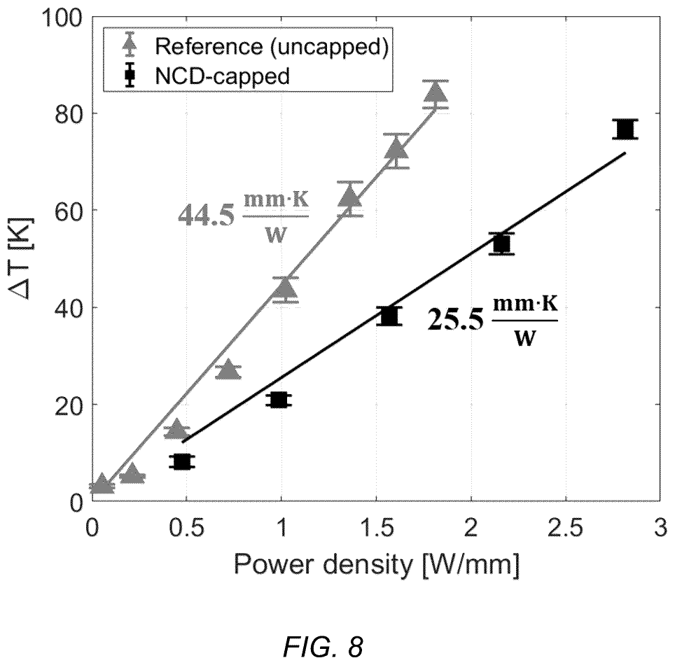

The plot in FIG. 8 shows the average temperature rise at the gate as a function of power density where the slope corresponds to the device thermal resistance. A 40% reduction in the thermal resistance at the gate electrode was observed with the incorporation of the NCD heat spreading layer when compared to a reference uncapped HFET. Optimization of the NCD/SiNₓ etch within the gate region will be required to maintain good device performance with the incorporation of this thermal management technique.

### Advantages and New Features

The main new feature introduced by the present invention is the reduced device temperature as measured by thermoreflectance imaging of the source/drain/gate metal contacts of the fabricated device. The thermal resistance reduction in the device from 44.5 mmK/W to 25.5 mmK/W, combined with the high maximum power density in the on state, are the best reported for a Gallium Oxide transistor to-date.

The improved thermal management of such Ga₂O₃-based devices provided by NCD films that can be deposited on the Ga₂O₃ due to the presence of a dielectric interlayer in accordance with the present invention leads to lower device operating temperature, increased carrier mobility, higher measured output current density, improved thermal budget, as well as improved overall device reliability.

Alternative approaches to thermal management in gallium oxide devices has been proposed via wafer bonding to higher thermal conductivity substrate such as silicon, silicon carbide, or diamond. See Y. Xu et al., “Direct wafer bonding of Ga₂O₃—SiC at room temperature,” Ceramics International 45 (5) 6552 (2019); M. Liao et al., “Interfacial Thermal Transport of Thinned and Chemical Mechanical Polished (−201) β-Ga2O3 Direct Wafer Bonded to (001) Si,” Electronic Materials Conference, 2022, pp. 110-111; and T. Matsumae et al., supra.

However, this approach has not resulted in levels of thermal resistance reduction observed via the top-side diamond capping approach of the present invention. Other alternative methods include capping via materials other than diamond, such as aluminum nitride, but again, such methods have been less effective due to lower thermal conductivity of the capping layer. See J. S. Lundh et al., “AlN-capped β-(AlₓGa₁₋ₓ)₂O₃/Ga₂O₃ heterostructure field-effect transistors for near-junction thermal management of next generation power devices,” Proc. Dev. Res. Conf. (2022).

### ALTERNATIVES

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein.

For example, although the present invention is described in the context of β-Ga₂O₃, an NCD/SiNₓ stack can also be used for thermal management of devices based on other forms of Ga₂O₃ such as α-Ga₂O₃, γ-Ga₂O₃, δ-Ga₂O₃, ε-Ga₂O₃, or κ-Ga₂O₃.

An NCD/SiNₓ or an NCD/SiO₂ stack in accordance with the present invention can also be incorporated into devices based on alloys of Ga₂O₃, such as devices based on (AlₓGa₁₋ₓ)₂O₃, where 0≤x≤1.

The present application contemplates any and all modifications within the spirit and scope of the underlying invention described and claimed herein, and all such modifications and alternative embodiments are deemed to be within the scope and spirit of the present disclosure.

What is claimed is:

1. A method for forming a Ga₂O₃-based electronic device having enhanced thermal management properties, comprising:
forming a Ga₂O₃-based buffer layer on a substrate;
forming a Ga₂O₃-based barrier layer on the Ga₂O₃-based buffer layer;
depositing a SiNₓ interlayer on the Ga₂O₃-based barrier layer; and
forming a nanocrystalline diamond (NCD) layer on the Ga₂O₃ barrier layer;
wherein the SiNₓ interlayer protects the Ga₂O₃ barrier layer from damage during formation of the NCD layer; and
wherein the NCD layer provides thermal management to the device.

2. The method according to claim 1, wherein the NCD layer is grown on the barrier layer capped Ga₂O₃ semiconductor.

3. The method according to claim 2, wherein the NCD layer is grown by microwave plasma enhanced chemical vapor deposition (MW-CVD) or hot filament CVD (HF-CVD).

4. The method according to claim 1, wherein the Ga₂O₃ is β-Ga₂O₃.

5. The method according to claim 1, wherein the buffer layer comprises unintentionally doped β-Ga₂O₃ and the barrier layer comprises β-(AlₓGa₁₋ₓ)₂O₃.

6. The method according to claim 1, further comprising doping the Ga₂O₃ buffer layer with a hydrogenic donor species.

7. The method according to claim 6, wherein the hydrogenic donor species comprises silicon (Si), germanium (Ge), or tin (Sn).

8. The method according to claim 1, further comprising forming source, gate, and drain electrodes to form a heterostructure field-effect transistor (HFET).

9. An Ga₂O₃-based electronic device having enhanced thermal management properties, comprising:
a Ga₂O₃-based buffer layer formed on a substrate;
a Ga₂O₃-based barrier layer formed on the Ga₂O₃-based buffer layer;
a SiNₓ interlayer deposited on the Ga₂O₃-based barrier layer; and
a nanocrystalline diamond (NCD) layer formed on the Ga₂O₃ barrier layer
wherein the SiNₓ interlayer protects the Ga₂O₃ barrier layer from damage during growth of the NCD layer; and
wherein the NCD layer provides thermal management to the device.

10. The device according to claim 9, wherein the Ga₂O₃ is β-Ga₂O₃.

11. The device according to claim 9, wherein the buffer layer comprises unintentionally doped β-Ga₂O₃ and the barrier layer comprises β-(AlₓGa₁₋ₓ)₂O₃.

12. The device according to claim 9, further comprising doping the Ga₂O₃ buffer layer with a hydrogenic donor species.

13. The device according to claim 9, wherein the hydrogenic donor species comprises silicon (Si), germanium (Ge), or tin (Sn).

14. The device according to claim 9, wherein the device is a heterostructure field-effect transistor (HFET), a field effect transistor (FET), a metal-oxide-semiconductor field effect transistor (MOSFET), a modulation-doped field effect transistor (MODFET), a current aperture vertical electron transistor (CAVET), a FinFET, or a hot electron transistor (HET).
